(19) United States
(12) Patent Application Publication
(10) Pub. No.: US 2012/0306567 A1
(43) Pub. Date: Dec. 6, 2012

(54) ADJUSTABLE CAPACITANCE STRUCTURE

(75) Inventor: Hyun-Sung HONG, Ontario (CA)

(73) Assignee: TAIWAN SEMICONDUCTOR MANUFACTURING COMPANY, LTD., Hsinchu (TW)

(21) Appl. No.: 13/118,759

(22) Filed: May 31, 2011

(51) Int. Cl. H03K 3/01; H01L 29/94

(52) U.S. Cl. 327/534; 257/300; 257/E29.345

(57) ABSTRACT

A capacitance structure comprises a plurality of metal oxide silicon (MOS) capacitors. A first end of each MOS capacitor of the plurality of MOS capacitors is coupled together at an effective node. A second end of each MOS capacitor of the plurality of MOS capacitors is configured to receive a respective different signal. Each first end of each MOS capacitor of the plurality of MOS capacitors thereby functions as an input end of a capacitor with a capacitance value determined based on the respective different signal. An effective capacitance value thereby results at the effective node.

### FIELD

The present disclosure is related to a capacitance structure.

### BACKGROUND

Generally, controlling time delay in digital designs is complicated and inflexible. In some approaches known to the applicants, each delay circuit for a delay path provides a fixed time delay. For example, if four different delay times are desired, four sets of delay circuits would have to be designed, each circuit corresponding to a delay time. For another example, once the circuit has been designed and/or implemented, an additional circuit would be designed and implemented, if an additional delay time is desired.

### BRIEF DESCRIPTION OF THE DRAWINGS

The details of one or more embodiments of the disclosure are set forth in the accompanying drawings and the description below. Other features and advantages will be apparent from the description, drawings, and claims.

FIGS. 1A-8A and 1B-8B are exemplary circuit diagrams of MOS capacitors in different configurations, in accordance with some embodiments.

FIGS. 1C-8C are plots of the C-V relationship of the MOS capacitors in FIGS. 1B-8B, respectively, in accordance with some embodiments.

FIG. 9 is a diagram of an exemplary circuit that uses MOS capacitors, in accordance with some embodiments.

FIG. 10 is a graph of waveforms illustrating an operation of the circuit in FIG. 9, in accordance with some embodiments.

FIG. 11 is a flow chart illustrating a method to acquire the effective capacitance of the circuit in FIG. 9, in accordance with some embodiments.

Like reference symbols in the various drawings indicate like elements.

### DETAILED DESCRIPTION

Embodiments, or examples, illustrated in the drawings are disclosed below using specific language. It will nevertheless be understood that the embodiments and examples are not intended to be limiting. Any alterations and modifications in the disclosed embodiments, and any further applications of the principles disclosed in this document are contemplated as would normally occur to one of ordinary skill in the pertinent art. Reference numbers may be repeated throughout the embodiments, but they do not require that feature(s) of one embodiment apply to another embodiment, even if they share the same reference number.

Some embodiments have one or a combination of the following features and/or advantages. The time delay mechanism is based on a resistance-capacitance (RC) circuit. The capacitance component is based on different configurations of metal-oxide-silicon capacitors (MOS capacitors or MOSCAPs), and is controllable to provide different capacitance values. Different capacitance values, together with a selected resistance value, provide different time delays. Because the capacitance is generated from MOSCAPs, the die area is small compared to the die area for other types of capacitors. The electrical current required to drive the MOSCAP, for example, from a driver, is reduced. The capacitive resolution represented by different capacitance values is easy to control.

### Exemplary Circuits

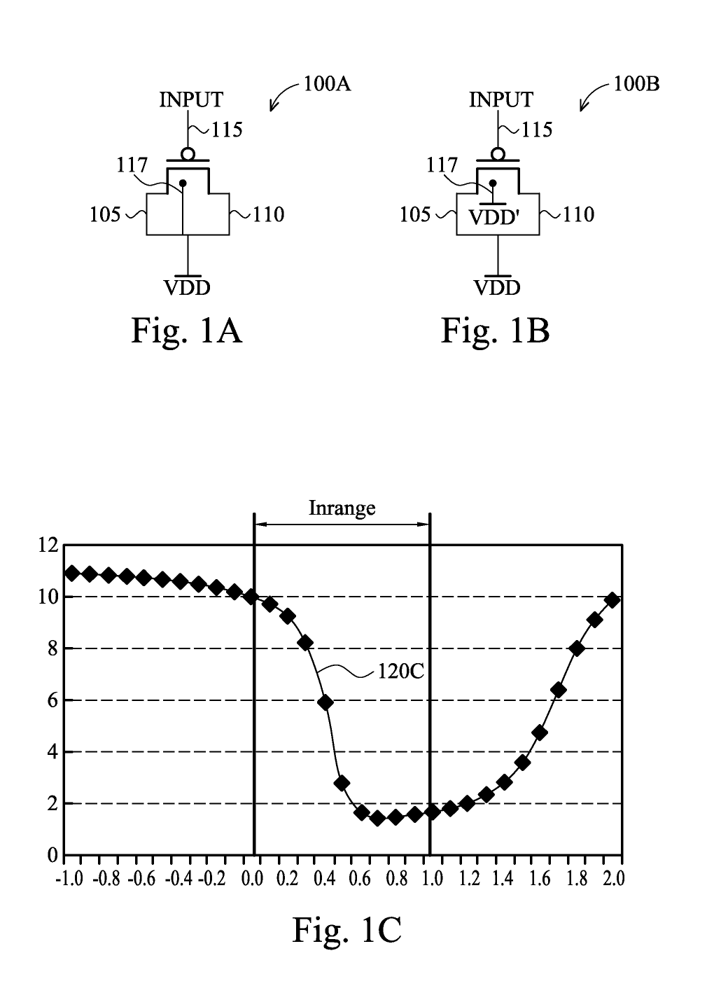

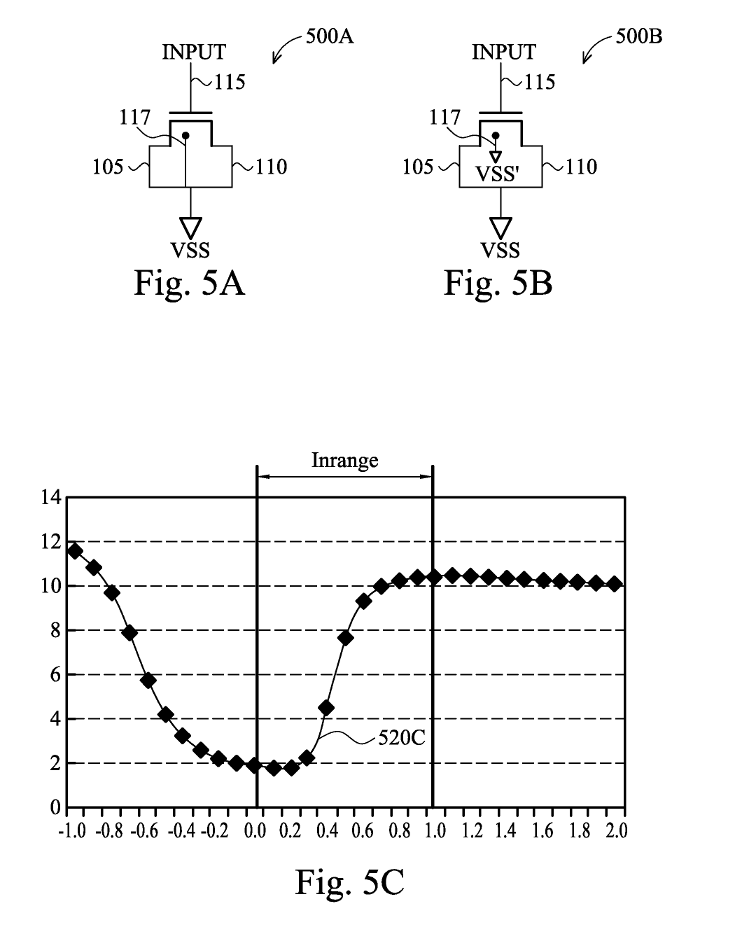

In this document, when a MOSCAP is formed by a P-channel MOS (PMOS) transistor, the MOSCAP is called a PMOSCAP. When a MOSCAP is formed by an N-channel MOS (NMOS) transistor, the MOSCAP is called an NMOSCAP. In the following illustration in FIGS. 1A-8A and 1B-8B, the respective MOSCAPs 100A-800A and 100B-800B are formed by a transistor 150A (not labeled) having a source 105, a drain 110, a gate 115, and a bulk 117. Transistor 150A is a PMOS transistor in FIGS. 1A-4A, and 1B-4B, and an NMOS transistor in FIGS. 5A-8A, and 5B-8B. Each MOSCAP includes an input terminal (input) and a voltage terminal. The capacitances seen at inputs of MOSCAPs 100A-800A are called C100A, C200A, C300A, C400A, C500A, C600A, C700A, and C800A (not labeled), respectively. Similarly, the capacitances seen at inputs of MOSCAPS 100B-800B are called C100B, C200B, C300B, C400B, C500B, C600B, C700B, and C800B (not labeled), respectively. In some embodiments, operational voltage VDD for each MOSCAP 100A-800A and 100B-800B is 0.9 V while ground reference voltage VSS is 0 V.

In FIGS. 1C-8C, the horizontal X-axes show the values of input voltage Vin (not labeled) applied at the input of each respective PMOSCAP 100B-800B in volts (V). The vertical Y-axis shows the values of capacitance C100B-C800B in femtofara (fF).

In some embodiments, capacitances C100B-C800B are used when input voltage Vin is in an input range Inrange of voltage VSS to voltage VDD or 0 V to ˜0.9 V. Different ranges for input range Inrange, however, are within the scope of various embodiments. The operational voltage range of each MOSCAP varies, depending on each of the technology nodes, e.g., 65 nm, 40 nm, 28 nm, etc. In some embodiments, curves 120C-820C in FIGS. 1C-8C are obtained by Simulations Program with Integrated Circuit Emphasis (HSPICE) in which voltage VSS is at 0 V and voltage VDD is at 0.9V. Those of ordinary skill in the art will recognize that curves 120C-820C vary when voltage VSS and/or voltage VDD vary.

FIG. 1A is a circuit diagram of a PMOSCAP 100A, in accordance with some embodiments. Drain 105, source 110, and bulk 117 are coupled together and to operational voltage VDD, and serve as the voltage terminal for PMOSCAP 100A. Gate 115 serves as the input for PMOSCAP 100A. FIG. 1B is a circuit diagram of a PMOSCAP 100B, in accordance with some embodiments. Compared with PMOSCAP 100A, bulk 117 of PMOSCAP 100B is not coupled to drain 105 or source 110, but is configured to receive a high logic level VDD′. In some embodiments, voltage VDD and VDD′ have the same voltage values, but voltage VDD′ is provided by a voltage source different from a voltage source providing operational voltage VDD. FIG. 1C is a plot illustrating the capacitance-voltage (C-V) relationship of PMOSCAP 100B, in accordance with some embodiments. Based on curve 120C, a capacitance value of capacitance C100B is provided on the Y-axis based on a value of input voltage Vin on the X-axis. The C-V relationship of PMOSCAP 100A and the capacitance values of PMOSCAPS 100A based on the C-V relationship are not described in this document, but should be recognizable by persons of ordinary skill in the art. Similarly, the C-V relationships of MOSCAP 200A-800A and the capacitance values of MOSCAPS 200A-800A are not described, but should be recognizable by persons of ordinary skill in the art.

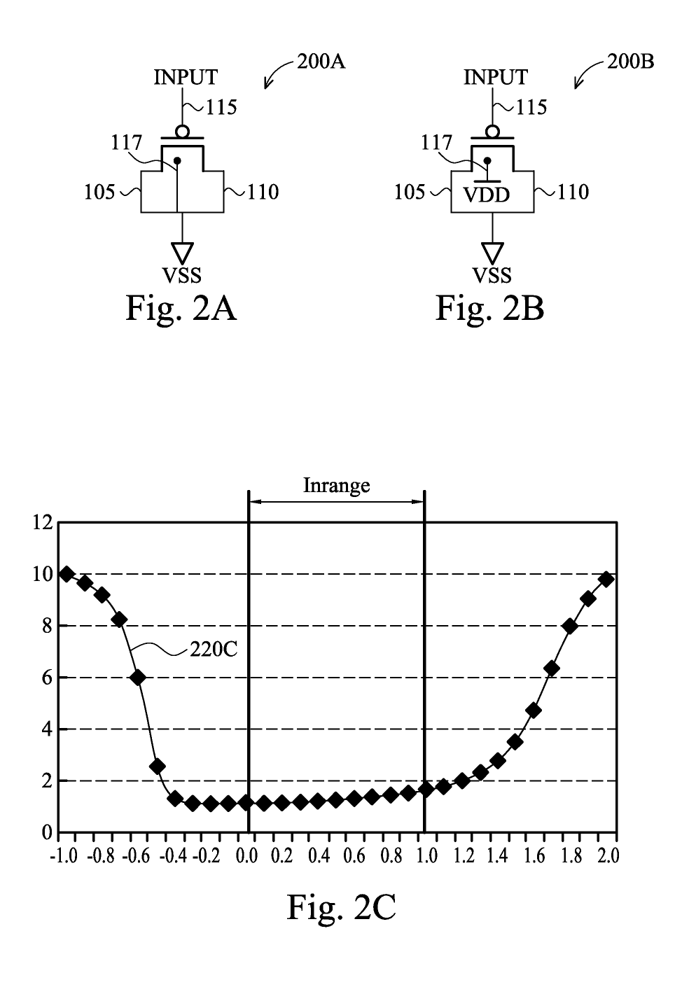

FIG. 2A is a circuit diagram of a PMOSCAP 200A, in accordance with some embodiments. Drain 105, source 110, and bulk 117 are coupled together and to ground reference voltage VSS, and serve as the voltage terminal for PMOSCAP 200A. Gate 115 serves as the input for PMOSCAP 100A. FIG. 2B is a circuit diagram of a PMOSCAP 200B, in accordance with some embodiments. Compared with PMOSCAP 200A, bulk 117 of PMOSCAP 200B is not coupled to drain 105 or source 110, but is configured to receive operational voltage VDD. FIG. 2C is a plot illustrating the C-V relationship of PMOSCAP 200B, in accordance with some embodiments. Based on curve 220C, a capacitance value of capacitance C200B is provided on the Y-axis based on a value of input voltage Vin on the X-axis.

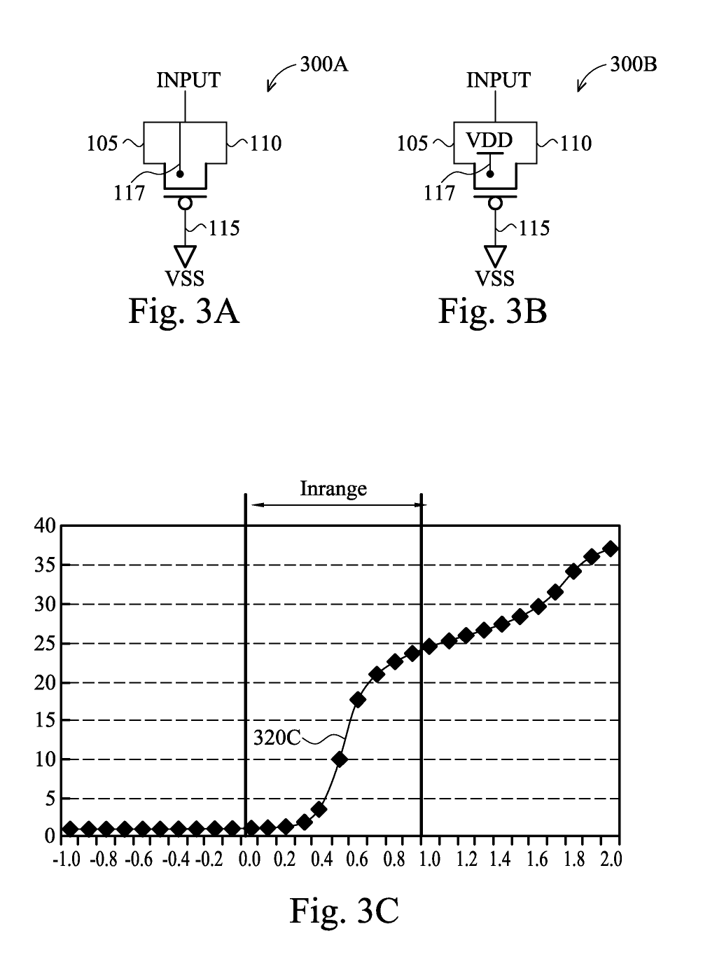

FIG. 3A is a circuit diagram of a PMOSCAP 300A, in accordance with some embodiments. Drain 105, source 110, and bulk 117 are coupled together, and serve as the input for PMOSCAP 300A. Gate 115 is coupled to voltage VSS, and serves as the voltage terminal for PMOSCAP 300A. FIG. 3B is a circuit diagram of a PMOSCAP 300B, in accordance with some embodiments. Compared with PMOSCAP 300A, bulk 117 of PMOSCAP 300B is not coupled to drain 105 or source 110, but is configured to receive operational voltage VDD. FIG. 3C is a plot illustrating the C-V relationship of PMOSCAP 300B, in accordance with some embodiments. Based on curve 320C, a capacitance value of capacitance C300B is provided on the Y-axis based on a value of input voltage Vin on the X-axis.

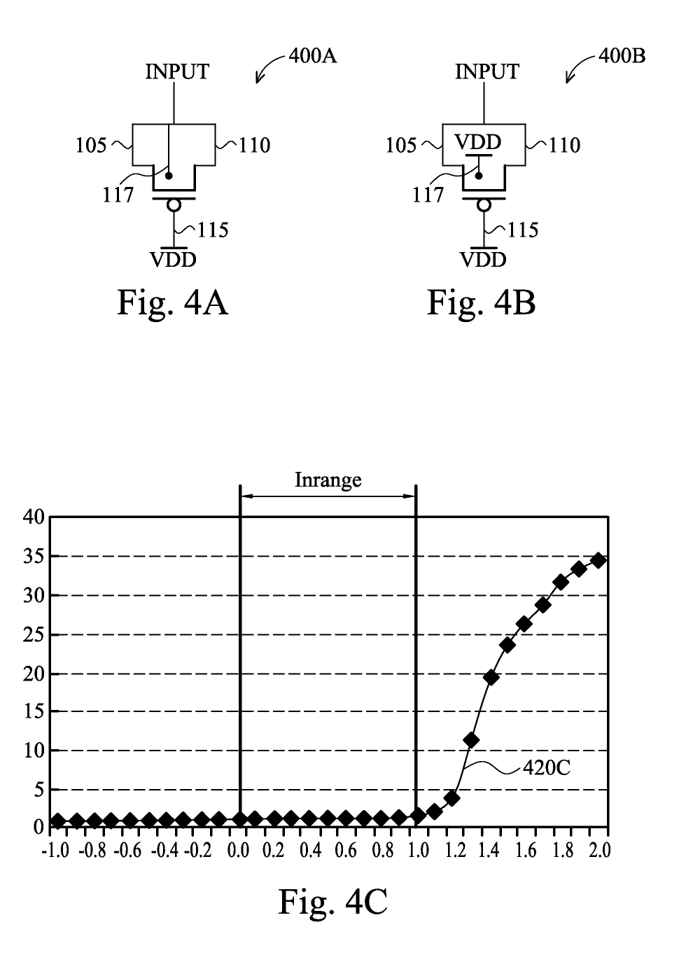

FIG. 4A is a circuit diagram of a PMOSCAP 400A, in accordance with some embodiments. Drain 105, source 110, and bulk 117 are coupled together, and serve as the input for PMOSCAP 300A. Gate 115 is coupled to voltage VDD, and serves as the voltage terminal for PMOSCAP 300A. FIG. 4B is a circuit diagram of a PMOSCAP 400B, in accordance with some embodiments. Compared with PMOSCAP 400A, bulk 117 of PMOSCAP 400B is not coupled to drain 105 or source 110, but is configured receive operational voltage VDD. FIG. 4C is a plot illustrating the C-V relationship of PMOSCAP 400B, in accordance with some embodiments. Based on curve 420C, a capacitance value of capacitance C400B is provided on the Y-axis based on a value of input voltage Vin on the X-axis.

FIG. 5A is a circuit diagram of an NMOSCAP 500A, in accordance with some embodiments. Drain 105, source 110, and bulk 117 are coupled together and to voltage VSS, and serve as the voltage terminal for NMOSCAP 500A. Gate 115 serves as the input for NMOSCAP 500A. FIG. 5B is a circuit diagram of an NMOSCAP 500B, in accordance with some embodiments. Compared with NMOSCAP 500A, bulk 117 of NMOSCAP 500B is not coupled to drain 105 or source 110, but is configured to receive a low logic level VSS′. In some embodiments, voltage VSS and voltage VSS′ have the same voltage values, but voltage VSS is provided by a voltage source different from a voltage source providing voltage VSS. FIG. 5C is a plot illustrating the C-V relationship of NMOSCAP 500B, in accordance with some embodiments. Based on curve 520C, a capacitance value of capacitance C500B is provided on the Y-axis based on a value of input voltage Vin on the X-axis.

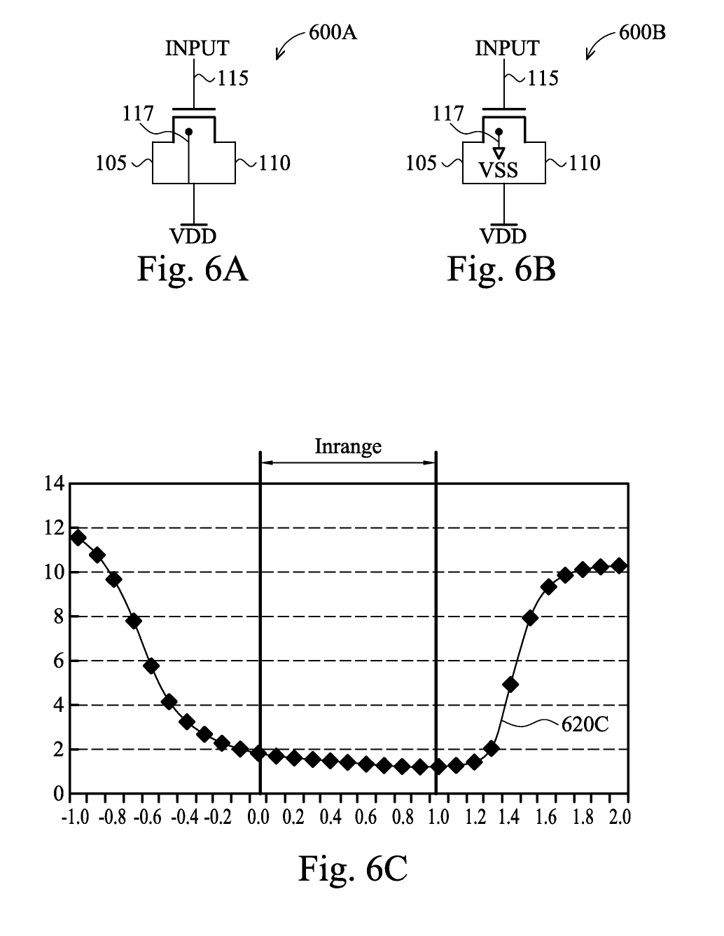

FIG. 6A is a circuit diagram of an NMOSCAP 600A, in accordance with some embodiments. Drain 105, source 110, and bulk 117 are coupled together and to voltage VDD, and serve as the voltage terminal for NMOSCAP 600A. Gate 115 serves as the input for NMOSCAP 600A. FIG. 6B is a circuit diagram of an NMOSCAP 600B, in accordance with some embodiments. Compared with NMOSCAP 600A, bulk 117 of NMOSCAP 600B is not coupled to drain 105 or source 110, but is configured to receive voltage VSS. FIG. 6C is a plot illustrating the C-V relationship of NMOSCAP 600B, in accordance with some embodiments. Based on curve 620C, a capacitance value of capacitance C600C is provided on the Y-axis based on a value of input voltage Vin on the X-axis.

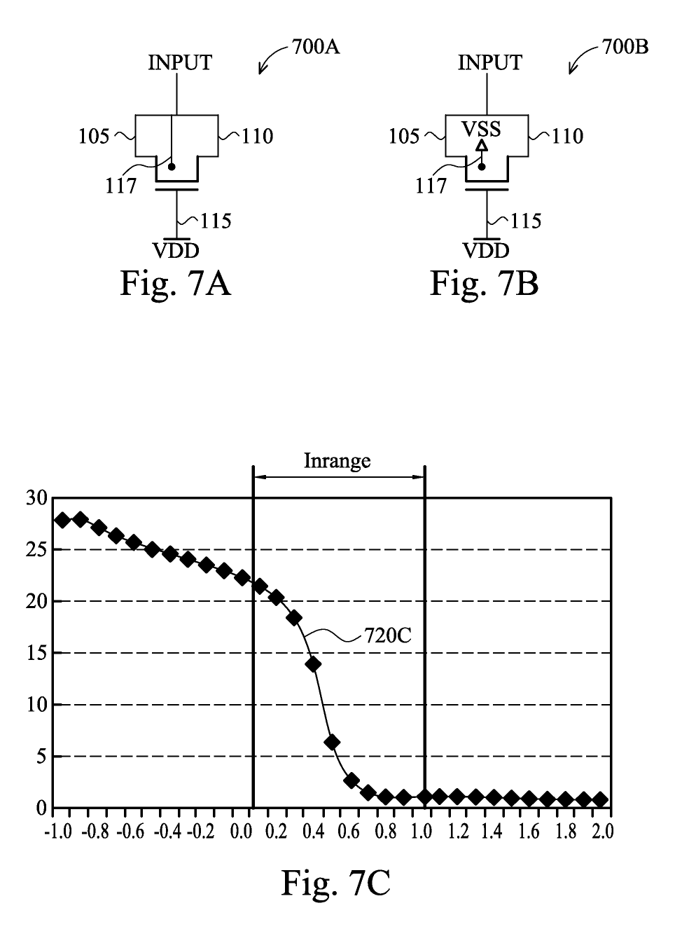

FIG. 7A is a circuit diagram of an NMOSCAP 700A, in accordance with some embodiments. Drain 105, source 110, and bulk 117 are coupled together, and serve as the input for NMOSCAP 700A. Gate 115 is coupled to voltage VDD, and serves as the voltage terminal for NMOSCAP 700A. FIG. 7B is a circuit diagram of an NMOSCAP 700B, in accordance with some embodiments. Compared with NMOSCAP 700A, bulk 117 of NMOSCAP 700B is not coupled to drain 105 or source 110, but is configured to receive voltage VSS. FIG. 7C is a plot illustrating the C-V relationship of NMOSCAP 700B, in accordance with some embodiments. Based on curve 720C, a capacitance value of capacitance C700B is provided on the Y-axis based on a value of input voltage Vin on the X-axis.

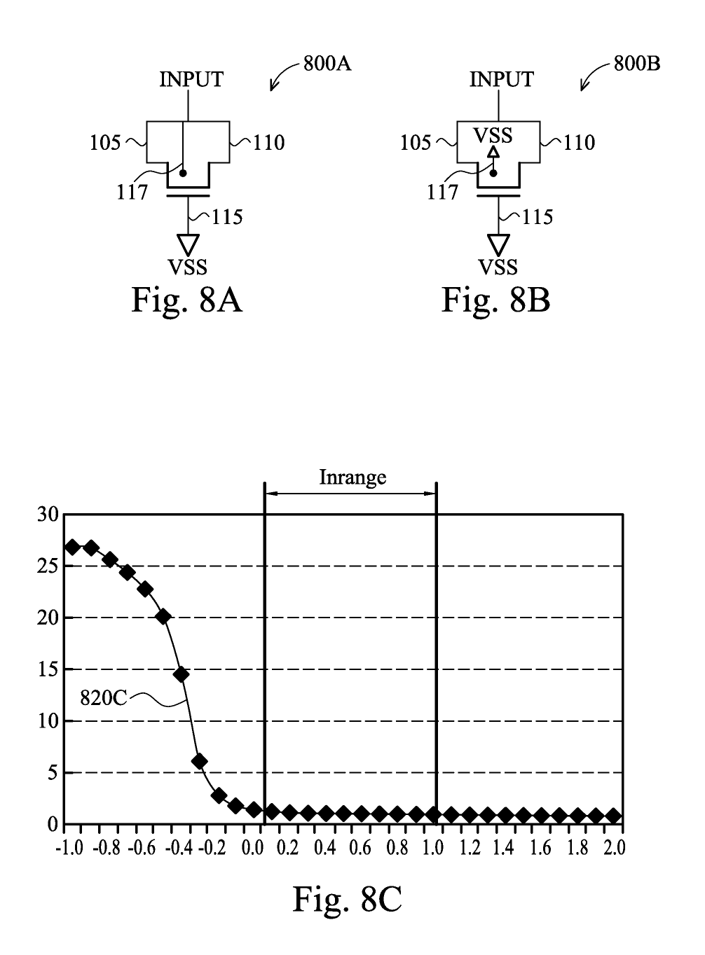

FIG. 8A is a circuit diagram of an NMOSCAP 800A, in accordance with some embodiments. Drain 105, source 110, and bulk 117 are coupled together, and serve as the input for NMOSCAP 800A. Gate 115 is coupled to voltage VSS, and serves as the voltage terminal for NMOSCAP 800A. FIG. 8B is a circuit diagram of an NMOSCAP 800B, in accordance with some embodiments. Compared with NMOSCAP 800A, bulk 117 of NMOSCAP 800B is not coupled to drain 105 or source 110, but is configured to receive voltage VSS. FIG. 8C is a plot illustrating the C-V relationship of NMOSCAP 800B, in accordance with some embodiments. Based on curve 820C, a capacitance value of capacitance C800B is provided on the Y-axis based on a value of input voltage Vin on the X-axis.

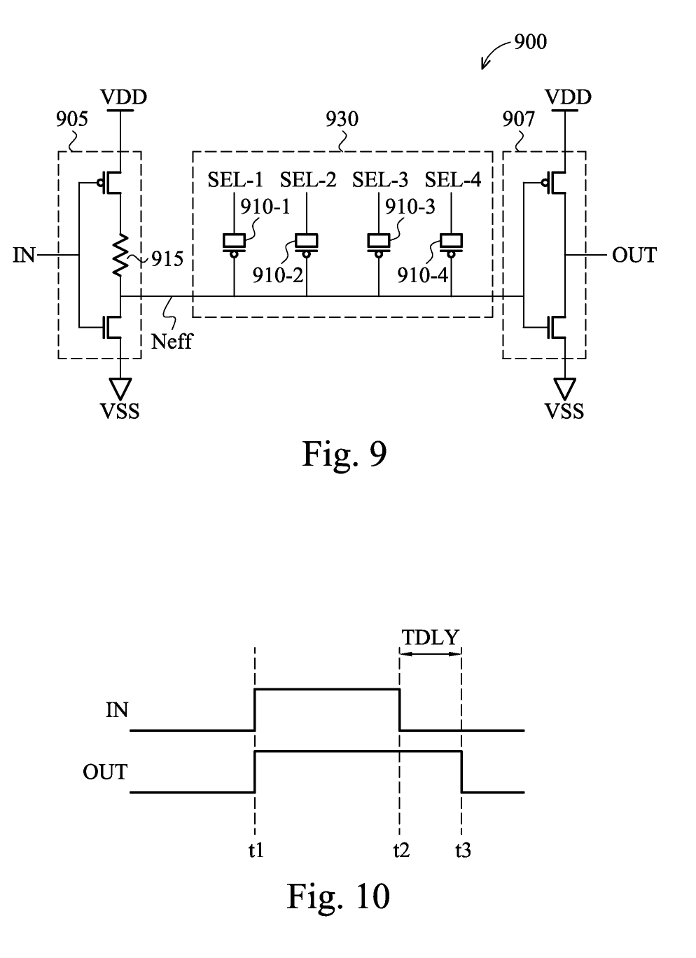

FIG. 9 is a diagram of an exemplary circuit 900 that uses MOSCAPs, in accordance with some embodiments. Inverters 905 and 907 are known in the art. The details of inverters 905 and 907 are not described. Inverter 905 is commonly called a driver.

Circuit 900 includes a capacitance structure 930 that includes a plurality of MOSCAPs 910. For illustration, however, four PMOSCAPs 910-1, 910-2, 910-3, 910-4 are shown. The operation of other MOSCAPs that are not shown should be recognizable by persons of ordinary skill in the art. In some embodiments, each of a MOSCAP 910 can be a PMOSCAP 100A, 100B, 200A, 200B, 300A, 300B, 400A or 400B or an NMOSCAP 500A, 500B, 600A, 600B, 700A, 700B, 800A, or 800B as illustratively shown above in FIGS. 1A-8A and 1B-8B. MOSCAPs 910 are coupled in parallel. Inputs of MOSCAPs 910 are coupled together and to one end of resistor 915.

Each of voltage terminals of MOSCAPs 910 receives a respective signal SEL. For illustration, PMOSCAPs 910-1, 910-2, 910-3, and 910-4 receive signals SEL-1, SEL-2, SEL-3, and SEL-4, respectively. In some embodiments, each of signals SEL has a binary value of zero (“0”) or one (“1”). A zero value corresponds to voltage VSS while a one value corresponds to voltage VDD. A binary value at a particular voltage level of a signal SEL corresponds to a capacitance value of the corresponding MOSCAP 910. For illustration, MOSCAP 910-1 is used. If MOSCAP 910-1 is a PMOSCAP, then if the corresponding signal SEL-1 is one, MOSCAP 910-1 functions as a PMOSCAP 100A because the voltage terminal of MOSCAP 910-1 is at voltage VDD. If signal SEL-1, however, is zero, MOSCAP 910-1 functions as a PMOSCAP 200A because the voltage terminal of MOSCAP 910-1 is at voltage VSS. For another example, MOSCAP 910-1 is an NMOSCAP. If the signal SEL-1 is zero, MOSCAP 910-1 functions as an NMOSCAP 500A because the voltage terminal of MOSCAP 910-1 is at voltage VSS. If signal SEL-1, however, is one, MOSCAP 910-1 functions as an NMOSCAP 600A because the voltage terminal of MOSCAP 910-1 is at voltage VDD, etc. In the above examples, the respective C-V curves for MOSCAPs 100A, 200A, 500A, and 600A are used to acquire a corresponding MOS capacitance based on a particular input voltage seen at node Neff. The operation of other MOSCAPs is similar to that of MOSCAP 910-1 as illustratively explained. Further, PMOSCAPs 100A and 200A, and NMOSCAPs 400A and 500A are used for illustration. A MOSCAP 910 can be another NMOSCAP or another PMOSCAP. A corresponding capacitance value then results, depending on the voltage value seen at node Neff based on a voltage value of the binary value of the corresponding signals SEL.

Various circuits providing the binary values to each signal SEL are within the scope of various embodiments. Such a circuit includes, for example, a buffer, an inverter, etc. In a buffer, the input of the buffer is passed through the output of the buffer. In an inverter, the input of the inverter is inverted to provide the inverted input at the output. The signal at the output is the corresponding signal SEL. In some embodiments, a logic gate is configured as a buffer or an inverter, and includes, for example, an AND gate, a NAND gate, an OR gate, a NOR gate, an exclusive OR gate, etc.

Once each of MOSCAPs 910-1, 910-2, 910-3, and 910-4 receives the corresponding binary values of signals SEL-1, SEL-2, SEL-3, and SEL-4, an effective capacitance value Ceff (not labeled) of four MOSCAPs 910-1, 910-2, 910-3, and 910-4 results at node Neff. In the illustration of FIG. 9, there are four MOSCAPs, and thus four signals SEL. As a result, there are 2⁴ or 16 effective capacitance values Ceff at node Neff, based on a combination of the binary values of four signals SEL-1, SEL-2, SEL-3, and SEL-4. Those of ordinary skill in the art will recognize that if K is an integer, and there are K MOSCAPs 910, there would be 2^{K} effective capacitance values Ceff at node Neff. In some embodiments, the value of each capacitance Ceff is obtained by simulation. In some embodiments, the voltage level of each binary value of zero or one of signals SEL also varies, providing different C-V characteristics, and thus a different capacitance value Ceff at a particular voltage seen at node Neff.

In some embodiments, each signal SEL is provided by a voltage source (not shown). As a result, the voltage value at each signal SEL varies depending on the values provided by the corresponding voltage source. The effective capacitance Ceff, as a result, varies depending on the voltage value provided by the voltage source of each signal SEL.

Resistor 915 in combination with effective capacitance Ceff results in an RC time delay TDLY illustratively shown in FIG. 10. In the example that there are 4 MOSCAPs 910-1, 910-2, 910-3, and 910-4, there are 16 effective capacitance values Ceff, and thus 16 time delay values TDLY. But if there are K MOSCAPs 910, there would be 2^{K} effective capacitance values Ceff corresponding to 2^{K} time delay values TDLY.

FIG. 10 is a graph of waveforms illustrating an operation of circuit 900, in accordance with some embodiments.

At time t1, signal IN switches from zero to one. Signal OUT follows signal IN. That is, signal OUT also switches from zero to one. In some embodiments, there is a time delay for signal OUT to follow signal IN, but the delay is insignificant compared to time delay TDLY. As a result, signal OUT is considered to follow signal IN that rises from zero to one at time t1.

At time t2, signal IN switches from one to zero. Signal OUT also follows signal IN, but is delayed by a time delay TDLY. In other words, signal OUT switches from one to zero at time t3. The value of time delay TDLY depends on the value of resistor 915 and the effective capacitance Ceff. For a given resistance value of resistor 915, however, a particular time delay TDLY depends on a particular value of effective capacitance Ceff. Various embodiments are advantageous over other approaches because, for example, for a given resistance value of resistor 915, time delay TDLY varies, depending on the different values of effective capacitance Ceff. As illustratively explained above, effective capacitance Ceff varies based on the voltage values of signals SEL applied at the corresponding MOSCAP 910. In other words, various embodiments benefit from a variable time delay TDLY based on a variable effective capacitance Ceff.

In the illustration of FIG. 10, the time delay TDLY occurs with reference to the falling edge of signal IN because MOSCAPs 910 are PMOSCAPs and resistor 915 is coupled between the PMOS transistor of driver 905 and node Neff. If MOSCAPs 910, however, are NMOSCAPs and resistor 915 is coupled between node Neff and the NMOS transistor of driver 905, the time delay would occur at the rising edge of signal IN. Different configurations between resistor 915 and the effective capacitance Ceff to generate different time delays TDLY are within the scope of various embodiments.

### Exemplary Method

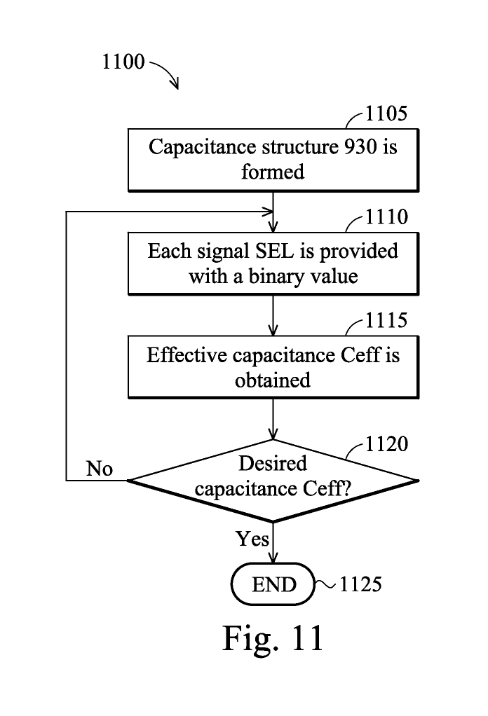

FIG. 11 is a flow chart of a method 1100, illustrating how effective capacitance Ceff is obtained, in accordance with some embodiments.

In step 1105, the capacitance structure 930 is formed. Each MOSCAP 910 is formed by a PMOS transistor or an NMOS transistor as a PMOSCAP or an NMOSCAP, respectively. For illustration, there are K MOSCAPs, and thus K corresponding signals SEL.

In step 1110, each signal SEL is provided with a binary value. As a result, there are there are K binary values corresponding to K signals SEL-1 to SEL-K.

In step 1115, the effective capacitance Ceff is obtained at node Ceff.

In step 1120, it is determined if the effective capacitance Ceff is the desired capacitance. If the effective capacitance Ceff is the desired capacitance, the method 1100 ends in step 1125. If not, one or a combination of signals SEL is adjusted until the desired capacitance Ceff is obtained. In effect, steps 1110 and 1115 are repeated until the desired capacitance Ceff is obtained.

In some embodiments, the voltage level for each binary value in step 1110 is adjustable. As a result, the effective capacitance Ceff changes accordingly. In some further embodiments, each voltage value for each signal SEL is provided by a corresponding voltage source. Consequently, the effective capacitance Ceff varies depending on the voltage values provided by the voltage sources.

A number of embodiments have been described. It will nevertheless be understood that various modifications may be made without departing from the spirit and scope of the disclosure. For example, resistor 915 in various figures is shown as a discrete resistor for illustration only, equivalent circuitry may be used. For another example, a resistive device, circuitry or network (e.g., a combination of resistors, resistive devices, circuitry, etc.) can be used in place of the resistor.

Some embodiments regard a capacitance structure comprising a plurality of metal oxide silicon (MOS) capacitors. A first end of each MOS capacitor of the plurality of MOS capacitors is coupled together at an effective node. A second end of each MOS capacitor of the plurality of MOS capacitors is configured to receive a respective different signal. Each first end of each MOS capacitor of the plurality of MOS capacitors thereby functions as an input end of a capacitor with a capacitance value determined based on the respective signal. An effective capacitance value thereby results at the effective node.

Some embodiments regard a method. In the method, an effective capacitance of a plurality of MOS capacitors is obtained. A first end of each MOS capacitor of the plurality MOS capacitors is coupled together at an effective node. A binary value is provided to a second end of each MOS capacitor of the plurality of MOS capacitors, thereby resulting in 2^{K} (binary values corresponding to K binary signals at K first ends of the plurality of MOS capacitors. K is the number of MOS capacitors of the plurality of MOS capacitors and is greater than one. For a respective binary value at the first ends of the plurality of MOS capacitors, the effective capacitance at the effective node is obtained. Each MOS capacitor of the plurality of capacitors is formed by a transistor having a drain, a source, a gate, and a bulk. The drain and the source are coupled together and are configured to serve as the first end, and the gate is configured to serve as the second end. Alternatively, the drain and the source are coupled together and are configured to serve as the second end, and the gate is configured to serve as the first end.

Some embodiments regard a method. In the method, each first end of a plurality of MOS capacitors is coupled together. An effective node is thereby formed. At least a voltage is provided at a second end of the plurality of MOS capacitors. An effective capacitance at the effective node is obtained. Each MOS capacitor of the plurality of MOS capacitors is formed by a transistor having a drain, a source, a gate, and a bulk. The drain and the source are coupled together and are configured to serve as the first end, and the gate is configured to serve as the second end. Alternatively, the drain and the source are coupled together and are configured to serve as the second end, and the gate is configured to serve as the first end.

The above methods show exemplary steps, but they are not necessarily performed in the order shown. Steps may be added, replaced, changed order, and/or eliminated as appropriate, in accordance with the spirit and scope of disclosed embodiments.

What is claimed is:

1. A capacitance structure comprising:
a plurality of metal oxide silicon (MOS) capacitors,
wherein
a first end of each MOS capacitor of the plurality of MOS capacitors is coupled together at an effective node; and
a second end of each MOS capacitor of the plurality of MOS capacitors is configured to receive a respective different signal, each first end of each MOS capacitor of the plurality of MOS capacitors thereby functions as an input end of a capacitor with a capacitance value determined based on the respective different signal, an effective capacitance value thereby resulted at the effective node.

2. The capacitance structure of claim 1, further comprising at least one circuit configured to generate a binary value as the respective different signal.

3. The capacitance structure of claim 2, wherein a circuit of the at least one circuit is selected from a group consisting of an inverter, a buffer, an AND gate, a NAND gate, an OR gate, a NOR gate, an exclusive OR gate.

4. The capacitance structure of claim 2, wherein the at least one circuit is configured to provide different voltage values for the binary value.

5. The capacitance structure of claim 1, further comprising at least one voltage source configured to provide a voltage as the respective different signal.

6. The capacitance structure of claim 1, wherein
each MOS capacitor of the plurality of MOS capacitors is formed by a transistor having a drain, a source, a gate, and a bulk;
the transistor is configured in one of the following ways:
the drain and the source are coupled together and are configured to serve as the first end, and the gate is configured to serve as the second end; and
the drain and the source are coupled together and are configured to serve as the second end, and the gate is configured to serve as the first end.

7. The capacitance structure of claim 6, wherein the bulk is configured in one of the following ways:
the bulk is coupled to the drain and the source;
the bulk is configured to receive a low logic level; and
the bulk is configured to receive a high logic level.

8. The capacitance structure of claim 1, wherein the plurality of MOS capacitors are all PMOS capacitors.

9. The capacitance structure of claim 1, wherein the plurality of MOS capacitors are all NMOS capacitors.

10. A method of obtaining an effective capacitance of a plurality of MOS capacitors, a first end of each MOS capacitor of the plurality MOS capacitors is coupled together at an effective node, the method comprising:
providing a binary value to a second end of each MOS capacitor of the plurality of MOS capacitors, thereby resulting in 2^{K} binary values corresponding to K binary signals at K first ends of the plurality of MOS capacitors, K being the number of MOS capacitors of the plurality of MOS capacitors and greater than one; and
for a respective binary value at the first ends of the plurality of MOS capacitors, obtaining the effective capacitance at the effective node,
wherein
each MOS capacitor of the plurality of capacitors is formed by a transistor having a drain, a source, a gate, and a bulk; and
the transistor is configured in one of the following ways:
the drain and the source are coupled together and are configured to serve as the first end, and the gate is configured to serve as the second end; and
the drain and the source are coupled together and are configured to serve as the second end, and the gate is configured to serve as the first end.

11. The method of claim 10, wherein the bulk is configured in one of the following ways:
the bulk is coupled to the drain and the source;
the bulk is configured to receive a low logic level; and
the bulk is configured to receive a high logic level.

12. The method of claim 10, wherein providing the binary value to the second end of each MOS capacitor of the plurality of MOS capacitors is done by a circuit selected from a group consisting of a buffer, an inverter, an AND gate, a NAND gate, an OR gate, a NOR gate, and an exclusive OR gate.

13. The method of claim 10, further comprising changing a voltage level of the binary value.

14. The method of claim 10, wherein the plurality of MOS capacitors is all PMOS capacitors.

15. The method of claim 10, wherein the plurality of MOS capacitors is all NMOS capacitors.

16. A method comprising:
coupling each first end of a plurality of MOS capacitors together, thereby forming an effective node;
providing at least a voltage value to a second end of a MOS capacitor of the plurality of MOS capacitors; and
obtaining an effective capacitance at the effective node,
wherein
each MOS capacitor of the plurality of capacitors is formed by a transistor having a drain, a source, a gate, and a bulk;
the transistor is configured in one of the following ways
the drain and the source are coupled together and are configured to serve as the first end, and the gate is configured to serve as the second end; or
the drain and the source are coupled together and are configured to serve as the second end, and the gate is configured to serve as the first end.

17. The method of claim 16, wherein the bulk is configured in one of the following ways:
the bulk is coupled to the drain and the source;
the bulk is configured to receive a low logic level; and
the bulk is configured to receive a high logic level.

18. The method of claim 16, wherein the voltage value is varied in a range.

19. The method of claim 16, wherein the plurality of MOS capacitors is all PMOS capacitors.

20. The method of claim 16, wherein the plurality of MOS capacitors is all NMOS capacitors.
